(19) United States
(12) Patent Application Publication
(10) Pub. No.: US 2008/0303060 A1
(43) Pub. Date: Dec. 11, 2008

(54) Semiconductor devices and methods of manufacturing thereof

(76) Inventors: Jin-Ping Han, Fishkill, NY (US); Henry Utomo, Newburgh, NY (US); Jiang Yan, Newburgh, NY (US); Alois Gutmann, Poughkeepsie, NY (US); Thomas W. Dyer, Pleasant Valley, NY (US)

Correspondence Address: SLATER & MATSIL LLP, 17950 PRESTON ROAD, SUITE 1000, DALLAS, TX, 75252, US

(21) Appl. No.: 11/810,633

(22) Filed: Jun. 6, 2007

(51) Int. Cl. H01L 29/778; H01L 21/20; H01L 21/336

(52) U.S. Cl. 257/190; 438/285; 438/494; 257/E21.09; 257/E29.246; 257/E21.403

(57) ABSTRACT

Semiconductor devices and methods of manufacturing thereof are disclosed. In a preferred embodiment, a method of manufacturing a semiconductor device includes providing a semiconductor wafer, forming a first material on the semiconductor wafer, and affecting the semiconductor wafer with a manufacturing process. The manufacturing process inadvertently causes a portion of the first material to be removed. The portion of the first material is replaced with a second material.

### TECHNICAL FIELD

The present invention relates generally to the fabrication of semiconductor devices, and more particularly to the fabrication of transistors.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET). A transistor typically includes a gate dielectric disposed over a channel region, and a gate formed over the gate dielectric. A source region and a drain region are formed on either side of the channel region within a substrate or workpiece.

What are needed in the art are improved methods of fabricating semiconductors such as transistors, and structures thereof.

### SUMMARY OF THE INVENTION

These and other problems are generally solved or circumvented, and technical advantages are generally achieved, by preferred embodiments of the present invention, which provide novel methods and structures for manufacturing semiconductor devices and transistors.

In accordance with a preferred embodiment of the present invention, a method of manufacturing a semiconductor device includes providing a semiconductor wafer, forming a first material on the semiconductor wafer, and affecting the semiconductor wafer with a manufacturing process. The manufacturing process inadvertently causes a portion of the first material to be removed. The method includes replacing the portion of the first material with a second material.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 4 show cross-sectional views of a semiconductor device at various stages of manufacturing in accordance with a preferred embodiment of the present invention, wherein recessed source and drain regions of a transistor are filled with a first material and a subsequent manufacturing process after the formation of first sidewall spacers results in the inadvertent removal of a portion of the first material from within the recesses;

FIG. 5a shows a cross-sectional view of a semiconductor device in accordance with a preferred embodiment wherein the removed portion of the first material is replaced with a material comprising the same material as the first material;

FIG. 5b shows a cross-sectional view of a semiconductor device in accordance with a preferred embodiment wherein the removed portion of the first material is replaced with a layer of silicon;

FIG. 5c shows a cross-sectional view of a semiconductor device in accordance with a preferred embodiment wherein the removed portion of the first material is replaced with a first layer comprising the same material as the first material and a second layer comprising silicon;

FIG. 6 shows the embodiments of the present invention shown in FIGS. 5a, 5b, and 5c after the formation of second sidewall spacers and a silicide, and after further manufacturing steps to form contacts that make electrical contact to transistor source and drain regions;

FIG. 7 shows a cross-sectional view of another preferred embodiment of the present invention, wherein a subsequent manufacturing process after the formation of second sidewall spacers results in the inadvertent removal of a portion of the first material from within the recesses, and wherein the first material is undercut beneath the second sidewall spacers;

FIG. 8 shows the embodiment of FIG. 7 after a second material is used to fill the area where the portion of the first material that was removed, and after the formation of a silicide over the second material;

FIG. 9 shows a cross-sectional view of yet another preferred embodiment of the present invention, wherein manufacturing processes performed after the first and second sidewall spacers are formed cause recessing of the source and drain material, and the recesses are filled in two deposition or growth processes after the inadvertent recessing occurs;

FIG. 10 is a cross-sectional view of an embodiment of the present invention implemented in one field effect transistor (FET) of a complementary metal oxide semiconductor (CMOS) device; and

FIG. 11 is a cross-sectional view of embodiments of the present invention implemented in both an n channel metal oxide semiconductor (NMOS) and a p channel metal oxide semiconductor (PMOS) FET of a CMOS device.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in specific contexts, namely implemented in single transistor devices and CMOS two-transistor device applications. Embodiments of the invention may also be implemented in other semiconductor applications such as memory devices and other applications. Embodiments of the invention may also be implemented in other semiconductor applications where manufacturing processes result in unintended removal of material, for example.

In some transistor applications, it is desirable to introduce stress in the channel region of the transistor, in order to increase the mobility of semiconductor carriers such as electrons and holes. One method used to induce strain is embedded SiGe (eSiGe), which involves creating a recess in the source and drain regions of a MOS transistor, and growing a doped SiGe film within the recess in lieu of conventional silicon source and drain regions. The larger crystal lattice of the eSiGe creates a stress in the channel between the source and drain and thereby enhances the carrier mobility.

However, after strained materials are formed, various subsequent manufacturing process steps may result in the undesired removal of the stressed materials that are intended to remain in the structure.

Embodiments of the present invention achieve technical advantages by repairing recessed strained material, by re-forming the strained material or replacing it at various stages of the manufacturing process. In some embodiments, the same material used to create the stress is used to refill the unintentionally recessed areas. In other embodiments, a different material is used to refill the unintentionally recessed areas. In some embodiments, the refill material comprises silicon, which improves the formation of a subsequently formed silicide, to be described further herein.

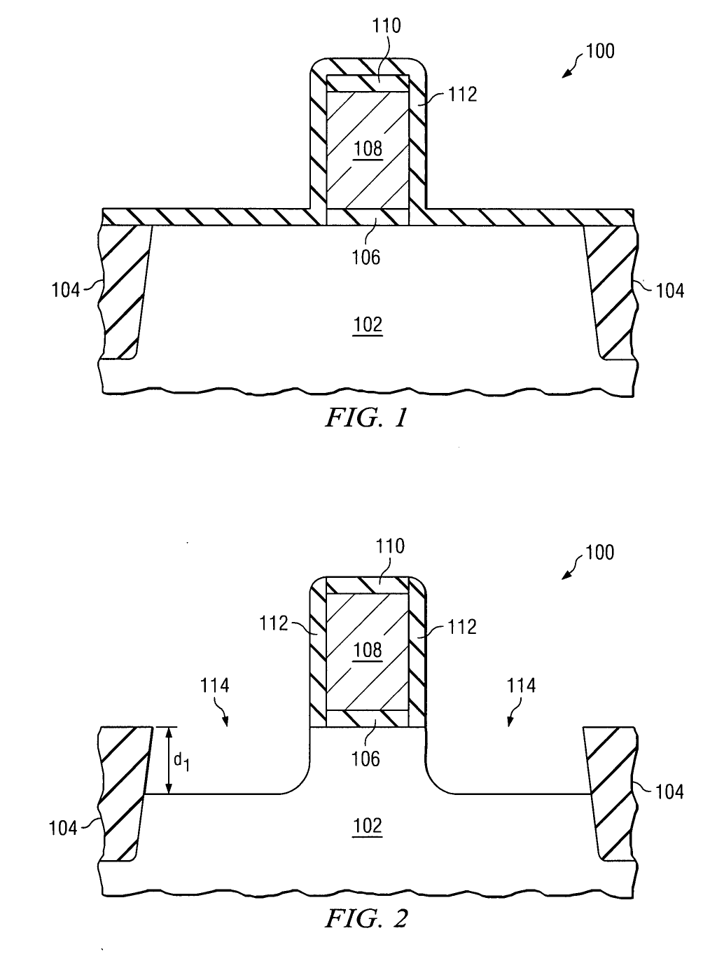

FIGS. 1 through 4 show cross-sectional views of a semiconductor device 100 at various stages of manufacturing in accordance with a preferred embodiment of the present invention, wherein recessed source and drain regions of a transistor 140 are filled with a first material 116 and a subsequent manufacturing process after the formation of first sidewall spacers 112 results in the inadvertent removal of a portion of the first material 116 from within the recesses 114.

To manufacture the semiconductor device 100, first, a workpiece 102 is provided. The workpiece 102 may include a semiconductor substrate comprising silicon or other semiconductor materials and may be covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may comprise a silicon-on-insulator (SOI) or a germanium-on-insulator (GOI) substrate, as examples.

Isolation regions 104 are formed in the workpiece 102. The isolation regions 104 may comprise shallow trench isolation (STI) regions, deep trench (DT) isolation regions, field oxide isolation regions, or other insulating regions, as examples. The isolation regions 104 may be formed by depositing a hard mask (not shown) over the workpiece 102 and forming trenches in the workpiece 102 and the hard mask using a lithography process. For example, the isolation regions 104 may be formed by depositing a photoresist, patterning the photoresist using a lithography mask and an exposure process, developing the photoresist, removing portions of the photoresist, and then using the photoresist and/or hard mask to protect portions of the workpiece 102 while other portions are etched away, forming trenches in the workpiece 102. The photoresist is then removed, and the trenches are then filled with an insulating material such as an oxide or nitride, or combinations thereof, as examples. The hard mask may then be removed. Alternatively, the isolation regions 104 may be formed using other methods and may be filled with other materials.

A gate dielectric material 106 is deposited over the workpiece 102 and the isolation regions 104. The gate dielectric material 106 preferably comprises about 200 Angstroms or less of an oxide such as SiO₂, a nitride such as Si₃N₄, a high-k dielectric material having a dielectric constant greater than 3.9, such as HfO₂, HfSiOₓ, Al₂O₃, ZrO₂, ZrSiOₓ, Ta₂O₅, La₂O₃, nitrides thereof, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}, or combinations and multiple layers thereof, as examples. Alternatively, the gate dielectric material 106 may comprise other dimensions and materials, for example. The gate dielectric material 106 may be formed using chemical vapor deposition (CVD), atomic layer deposition (ALD), metal organic chemical vapor deposition (MOCVD), physical vapor deposition (PVD), or jet vapor deposition (JVD), as examples, although alternatively, other methods may also be used.

A gate material 108 is deposited over the gate dielectric material 106. The gate material 108 preferably comprises an electrode material. The gate material 108 preferably comprises a thickness of about 1,500 Angstroms or less, for example. The gate material 108 preferably comprises a semiconductor material, such as polysilicon or amorphous silicon; a metal such as TiN, HfN, TaN, W, Al, Ru, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, TaC, TaCN, TaCNO, or other metals; a partially or fully silicided gate material (FUSI), having a silicide layer comprised of titanium silicide, nickel silicide, tantalum silicide, cobalt silicide, or platinum silicide; and/or combinations or multiple layers thereof, as examples. The gate material 108 may comprise a variety of different stoichiometry combinations for the components of the exemplary metals listed, for example. Alternatively, the gate material 108 may comprise other dimensions and materials, for example. The gate material 108 may be formed by CVD, PVD, or other suitable deposition methods, for example. The gate material 108 may optionally be implanted with dopants; e.g., the gate material 108 may be predoped or may be doped later, at the same time source and drain regions are implanted with dopants.

A hard mask 110 is deposited over the gate material 108. The hard mask 110 may comprise a nitride material such as silicon nitride, an oxide material such as silicon dioxide, a nitridized oxide, or multiple layers and combinations thereof, for example, although alternatively, the hard mask 110 may comprise other materials. In some embodiments, the hard mask 110 may comprise a trilayer including two nitride layers with an oxide layer disposed between the nitride layers. A plurality of alternating silicon dioxide layers and silicon nitride layers may be used for the hard mask 110, to provide etch selectivity and etch stop layers for subsequent etch processes, for example. The hard mask 110 may prevent the formation of semiconductive material in subsequent processing steps over the gate material 108, for example. The hard mask 110 preferably comprises about 500 Angstroms or less of silicon nitride and/or silicon dioxide, although alternatively, the hard mask 110 may comprise other dimensions and materials.

The hard mask 110, the gate material 108, and the gate dielectric material 106 are patterned using lithography to form a gate 108 and gate dielectric 106 with a patterned hard mask 110 residing on top, as shown in FIG. 1. The workpiece 102 may be lightly doped with a dopant species to form lightly doped regions (not shown) in a top surface of the workpiece 102 proximate the gate 108 and gate dielectric 106, after the patterning of the gate 108 and the gate dielectric 106. Other implantation processes (e.g., pocket implants, halo implants, or double-diffused regions) may also be performed as desired after the patterning of the gate 108 and gate dielectric 106, for example.

A sidewall spacer material 112 is formed over the top surface of the hard mask 110, the workpiece 102, and the isolation regions 104, and over the sidewalls of the gate 108, gate dielectric 106, and hard mask 110, as shown in FIG. 1. The sidewall spacer material 112 may comprise one or more liners and may comprise two or more layers of insulating material, e.g., such as silicon nitride, silicon oxide, and/or silicon oxynitride, although other materials may also be used. The sidewall spacer material 112 may comprise an oxide liner and a nitride layer disposed over the oxide liner, as an example. The sidewall spacer material 112 is preferably conformal as-deposited, as shown in FIG. 1.

The sidewall spacer material 112 is preferably etched using an anisotropic or directional etch process, leaving sidewall spacers 112 on the sidewalls of the gate 108, gate dielectric 106, and hard mask 110, as shown in FIG. 2. The anisotropic etch process removes the sidewall spacer material 112 from the top surfaces of the hard mask 110, the workpiece 102, and the isolation regions 104, leaving sidewall spacers 112 on the sidewalls of the hard mask 110, gate 108, and gate dielectric 106. The sidewall spacers 112 may comprise downwardly-sloping sidewalls as shown due to the anisotropic etch process, for example.

After the formation of the sidewall spacers 112, which are also referred to herein as first sidewall spacers 112, optionally, the workpiece 102 may be implanted with a deep implantation of a dopant species proximate the first sidewall spacers 112, not shown. The first sidewall spacers 112 may comprise temporary sidewall spacers that are later removed and replaced with permanent first sidewall spacers 112 that remain in the structure in some embodiments, for example. Alternatively, the first sidewall spacers 112 may comprise permanent sidewall spacers, as another example.

Exposed portions of the workpiece 102 are then recessed using an etch process, e.g., using an etch process adapted to remove the workpiece 102 material and not the isolation region 104 material, hard mask 110, or sidewall spacers 112, forming recesses 114 in the workpiece 102 proximate a first side and a second side of the gate 108 and gate dielectric 106, as shown in FIG. 2. The recesses 114 preferably comprise a depth beneath the top surface of the workpiece 102 comprising a dimension d₁ of about 200 nm or less, for example. The recesses 114 preferably comprise a width of about 900 nm to 1 μm or less in some embodiments, as another example. Alternatively, the recesses 114 may comprise other dimensions. The recesses 114 may comprise substantially oval, round, square, rectangular, triangular, or trapezoidal shapes, as examples, although alternatively, the recesses 114 may comprise other shapes.

The recesses 114 comprise two holes in the top surface of the workpiece 102 formed on either side of the gate 108 and gate dielectric 106. The etch process to form the recesses 114 may be substantially anisotropic, etching material preferentially in a downward direction, as shown. Alternatively, the etch process to form the recesses 114 may be isotropic, slightly undercutting the workpiece 102 beneath the sidewall spacers 112, not shown in the drawings. The etch process to form the recesses 114 may alternatively be partially anisotropic and partially isotropic, as another example. The etch process to form the recesses 114 may comprise a reactive ion etch (RIE) process, or a dry or wet etch process, as examples. Only two recesses 114 are shown in the figures; however, alternatively, preferably a plurality of recesses 114 are simultaneously formed (e.g., a plurality of transistors 140 are preferably formed at once across the workpiece 102).

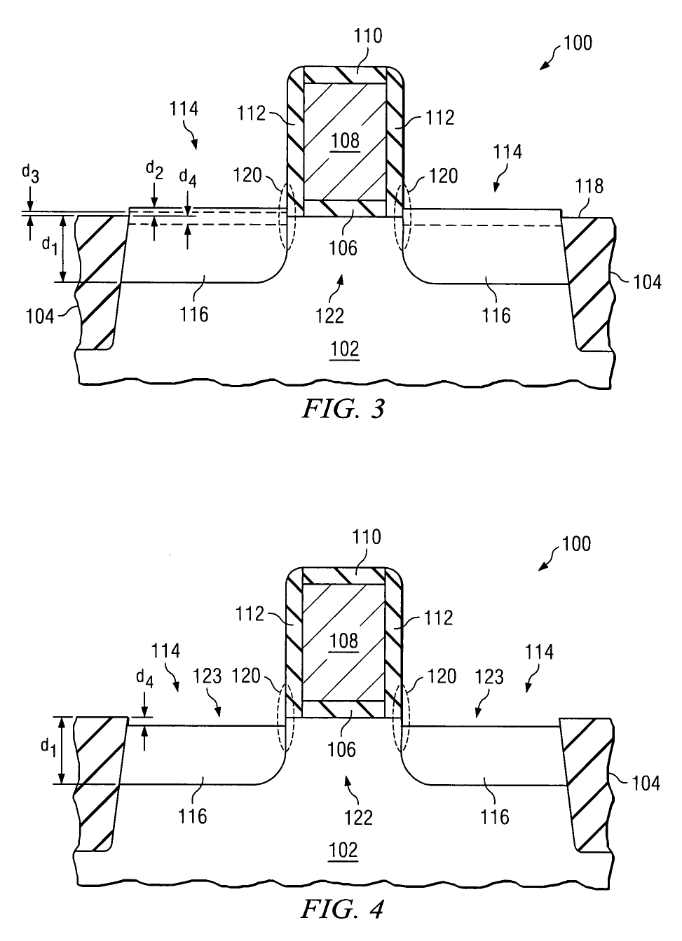

Next, in accordance with an embodiment of the present invention, the recesses 114 are filled with a first material 116, as shown in FIG. 3. The first material 116 is also referred to herein as a first semiconductive material 116, for example. The first material 116 preferably completely fills the recesses 114 in the entire amount of the depth beneath the top surface of the workpiece 102 comprising the dimension d, of about 200 nm or less, for example. In some embodiments, the first material 116 preferably overfills the recesses 114 by an amount of dimension d₂ above the top surface 118 of the workpiece 102, wherein dimension d₂ preferably comprises about 0 to 50 nm as deposited, for example. Alternatively, the first material 116 may overfill the recesses 114 by other amounts, for example.

The first semiconductive material 116 preferably comprises a compound semiconductor material comprising silicon (Si) and at least one other element, for example. The other element(s) preferably comprises an atom having a different size than Si and/or a different atom size than the material of the workpiece 102, so that stress is created in the first semiconductive material 116 which is bounded on both sides by the workpiece 102, for example. The first semiconductive material 116 preferably comprises a material adapted to alter a stress of the workpiece 102 in a region of the workpiece 102 proximate the first semiconductive material 116 in some embodiments. The first material 116 may also comprise other materials, e.g., that may or may not affect the stress of the adjacent workpiece 102.

In some embodiments, for example, the first semiconductive material 116 is preferably adapted to alter the stress of the adjacent channel region 122 disposed between source and drain regions comprising the first semiconductive material 116. The first semiconductive material 116 preferably comprises SiGe, carbon-doped SiGe, or SiC, to be described further herein, although alternatively, the first semiconductive material 116 may also comprise other materials. A first semiconductive material 116 comprising SiGe or carbon-doped SiGe introduces or increases tensile stress of the source region and the drain region, which creates compressive stress on the channel region 122, for example. A first semiconductive material 116 comprising SiC introduces or increases compressive stress of the source region and the drain region, which creates tensile stress on the channel region 122. Alternatively, the first semiconductive material 116 may comprise other compound semiconductor materials, for example.

The first semiconductive material 116 is preferably epitaxially grown in some embodiments. The first semiconductive material 116 preferably forms only on the exposed, recessed surfaces of the workpiece 102 in the epitaxial growth process. Alternatively, the first semiconductive material 116 may be deposited, using ALD, PVD, CVD, or other deposition methods, for example, and the first semiconductive material 116 may be patterned to remove the first semiconductive material 116 from over the isolation regions 104, the hard mask 110, the first sidewall spacers 112, and other undesired regions of the workpiece 102.

Next, the workpiece 102 is affected with a manufacturing process. The manufacturing process preferably comprises a process that is intended to not cause any removal of the first material 116 from within the trenches 114. The manufacturing process may comprise a cleaning process, a polishing process, an etch process, or removal process for a material layer of the semiconductor device 100 other than the first material 116 as examples, or combinations thereof, although the manufacturing process may alternatively comprise other processes. However, the manufacturing process disadvantageously inadvertently or unintentionally causes a top portion of the first material 116 to be removed from the recesses 114, which is remedied by embodiments of the present invention, to be described further herein.

Reactive ion etch (RIE) processes and other etch processes used to remove various material layers from over the workpiece 102 may be particularly damaging to the first material 116, for example. Often, many cleaning steps are used during the processing of semiconductor device 100, and each cleaning step may remove a small amount of the first material 116, so that little-by-little a relatively large top portion of the first material 116 is removed.

The first material 116 may be recessed slightly by the manufacturing process, as shown at d₃ in phantom, wherein a portion of the first material 116 is left remaining above the top surface of the workpiece 102. However, some manufacturing processes may result in excessive recessing of the first material 116 below the top surface 118 of the workpiece 102, as shown at d₄ in phantom in FIG. 3 and also shown in FIG. 4 as recess 123. In these embodiments, the excessive recesses 123 formed in the first material 116 may result in device failures in some applications. For example, regions 120 proximate the channel region 122 are left exposed, and shorts may form in these areas during subsequent deposition or other manufacturing processes.

Note that other manufacturing processes may be performed on the workpiece 102 that do not result in recessing of the first material 116, either before or after the manufacturing process or processes that caused the unintended excessive recessing 123. Furthermore, a plurality of manufacturing processes may cause unintentional or inadvertent recessing of the first material 116, for example.

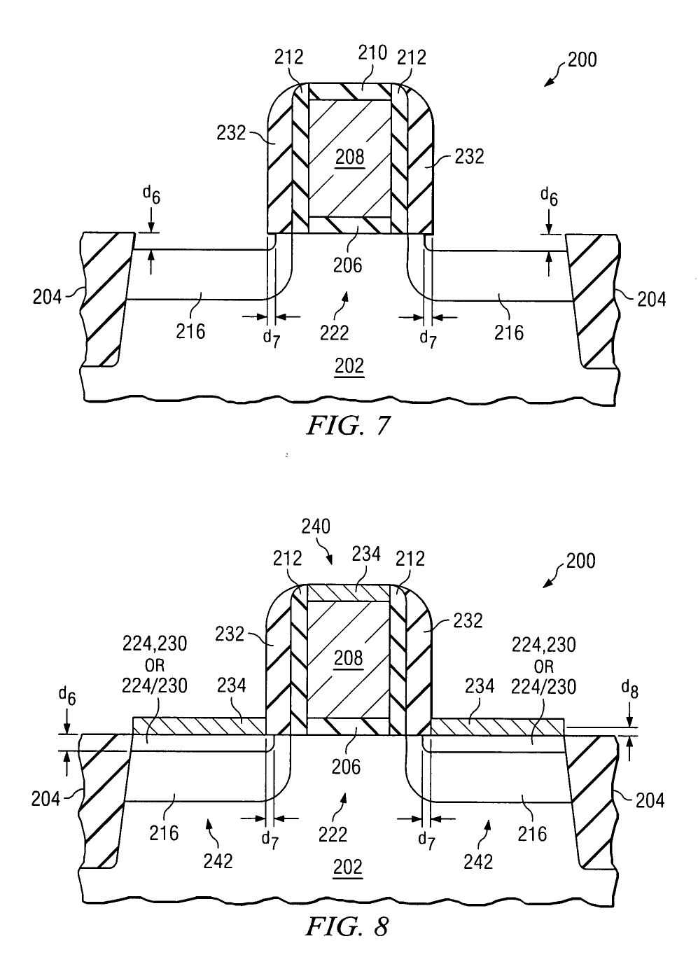

Note also that in some embodiments, the manufacturing process that results in the inadvertent removal of the top portion of the first material 116 may also result in removing a portion of the first material 116 from under the first sidewall spacer 112, undercutting the first sidewall spacer 112, not shown in FIGS. 3 and 4; see the embodiment shown in FIG. 7.

In some embodiments, at the point in the manufacturing process shown in FIG. 4, a portion of the hard mask 110 may have been removed during the various manufacturing processes used. For example, a single layer of oxide or nitride of the hard mask 110 may be left remaining on the semiconductor device 100 at this point.

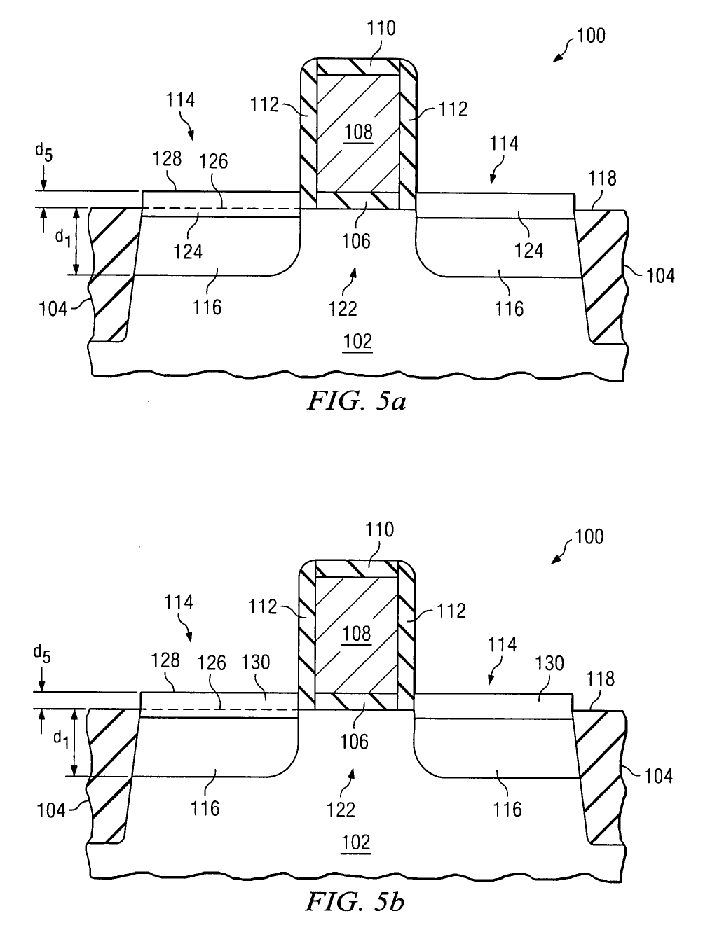

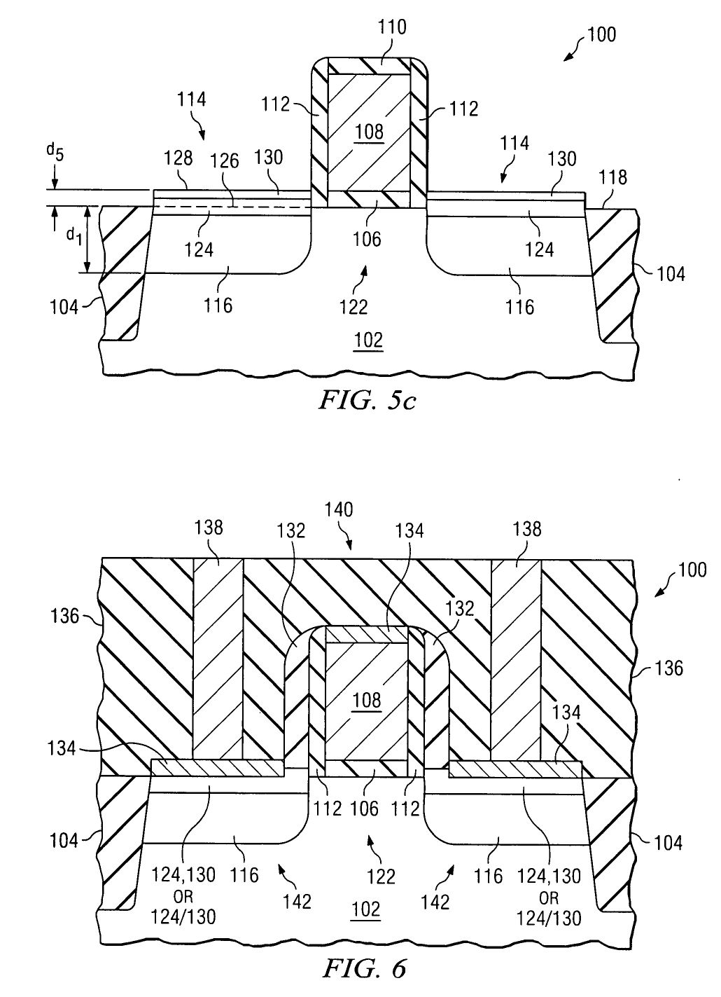

In accordance with embodiments of the present invention, the unintended or inadvertent recessing 123 of the first material 116, or alternatively a slight recessing of the first material 116 shown in phantom at d₃ in FIG. 3, is repaired using a second material. In particular, the top portion of the first material 116 that is removed is replaced with a second material, as shown in FIGS. 5a, 5b, and 5c. The second material repairs or replaces the excessive recesses 123 formed in the first material 116. The second material may comprise the same material as the first material 116, as shown in FIG. 5a, the second material may comprise a layer of silicon or other material different than the first material 116, as shown in FIG. 5b, or both, as shown in FIG. 5c. The second material preferably comprises Si, SiGe, carbon-doped SiGe, SiC, or combinations or multiple layers thereof, for example.

FIG. 5a shows a cross-sectional view of a semiconductor device 100 in accordance with a preferred embodiment of the present invention wherein the unintentionally removed portion of the first material 116 is replaced with a second material 124 that comprises the same material as the first material 116. If the first material 116 comprises SiGe, the second material 124 preferably comprises SiGe in this embodiment, as one example. The second material 124 preferably comprises a compound semiconductor material in some embodiments and may be adapted to create stress in the adjacent workpiece 102, although other materials may also be used, for example.

FIG. 5b shows a cross-sectional view of a semiconductor device 100 in accordance with a preferred embodiment wherein the removed portion of the first material 116 is replaced with a second material 130 comprising a layer of silicon. This embodiment is advantageous if a silicidation process is later used to form a silicide over the source and drain regions comprised of the first material 116 and the second material 130, because the silicidation process is improved, for example. The second material 130 may comprise other materials adapted to improve the formation of a silicide, for example. Alternatively, the second material 130 may comprise other materials that are different than the first material 116 in this embodiment. As one example, if the first material 116 comprises SiGe, the second material 130 may comprise carbon-doped SiGe, although other materials may also be used. The second material 130 may also comprise a single element semiconductor material in this embodiment, for example.

FIG. 5c shows a cross-sectional view of a semiconductor device 100 in accordance with yet another preferred embodiment of the present invention, wherein the removed portion of the first material 116 is replaced with a first layer 124 comprising the same material as the first material and a second layer 130 comprising silicon. Alternatively, the first layer 124 and the second layer 130 may comprise other materials, such as the materials listed for materials 124 and 130 shown in FIGS. 5a and 5b, as examples.

Thus, replacing the unintentionally recessed portion of the first material 116 with the second material 124, 130, or 124/130 may comprise forming the same material 124 as the first material 116, a different material 130 than the first material 116, or combinations or multiple layers thereof (e.g., 124/130 shown in FIG. 5c), for example, in accordance with embodiments of the present invention.

The second material 124, 130, or 124/130 may be epitaxially grown, or alternatively the second material 124, 130, or 124/130 may be deposited, for example. In some embodiments, the first material 116 and/or the second material 124, 130, or 124/130 are preferably formed or grown epitaxially. For example, the workpiece 102 may be placed in a processing chamber, and then gas sources may be introduced into the processing chamber to epitaxially grow the first material 116 to fill the recesses 114, and to epitaxially grow the second material 124, 130, or 124/130 to repair or replace the missing top portion of the first material 116. A gas source comprising Si (e.g., SiH₄ or SiH₂Cl₂) may be introduced into the processing chamber to form a layer of silicon 130, for example. A first gas source comprising Si (e.g., SiH₄ or SiH₂Cl₂) and a second gas source comprising Ge (e.g., GeH₄) and/or C (e.g., CH₃Si) may be introduced into the processing chamber to form SiGe or SiC, for example. Alternatively, other gas sources may be used, and other gases may be included in the gas mixture, such as carrier gases and dopant source gases. An example of a carrier gas is HCl and an example of a p-type dopant source is B₂H₆, although alternatively, other gases may be used. If a dopant source gas is not included in the gas mixture, the source and drain regions 142 may be doped later, after the recesses 123 in the first material 116 are filled with the second material 124, 130, or 124/130, for example.

Advantageously, if an epitaxial process is used to form the first and second semiconductive materials 116 and 124, 130, or 124/130, a lithography process to remove undesired first and second semiconductive materials 116 and 124, 130, or 124/130 may be avoided, because the semiconductive materials 116, 124, 130, or 124/130 only form on the exposed portions of the workpiece 102 in the recesses 114, for example. Thus, the number of lithography steps and lithography mask sets required to manufacture the semiconductor device 100 may be reduced.

The second material 124, 130, or 124/130 is preferably formed to a height at least level with the top surface 118 of the workpiece 102 as shown at 126 in FIGS. 5a through 5c. More preferably in some embodiments, the second material 124, 130, or 124/130 overfills the recessed first material 116, as shown. The second material 124, 130, or 124/130 may comprise a top surface 128 that extends above the top surface 118 of the workpiece by a dimension d₅, as shown. Dimension d₅ preferably comprises about 0 to 50 nm in some embodiments, for example, although alternatively, dimension d₅ may comprise other dimensions. A portion of the second material 124, 130, or 124/130 may be consumed during a subsequent silicide process, so overfilling the recessed first material 116 may be advantageous in some applications, for example. Furthermore, additional manufacturing processes may cause the inadvertent removal of the second material 124, 130, or 124/130, and overfilling the recessed first material 116 may result in preventing the need to repair or replace repeatedly recessed portions of the second material 124, 130, or 124/130 from subsequent manufacturing processes, for example.

Note that in some embodiments, the isolation regions 104 may be recessed below the top surface of the workpiece 102, not shown in the drawings.

The total thickness of the second material 124, 130, or 124/130 depends on the amount of recess of the first material 116. The second material 124, 130, or 124/130 may comprise a thickness of about 100 nm or less, and may comprise a thickness of about 150 nm or less in some embodiments. Alternatively, the thickness of the second material 124, 130, or 124/130 may comprise other dimensions.

The manufacturing process for the semiconductor device 100 is then continued to complete the fabrication of the device 100. For example, in FIG. 6, a cross-sectional view of a portion of a completed semiconductor device 100 is shown. Second sidewall spacers 132 comprising similar materials and/or liners as described for the first sidewall spacers 112 are formed over the first sidewall spacers 112, using a similar method described for the first sidewall spacers 112. The first semiconductive material 116 and the second semiconductive material 124, 130, or 124/130 on either side of the gate dielectric 106 and the gate 108 form the source and drain regions 142 of the transistor 140. Doped or implanted portions of the workpiece 102 proximate the first and second semiconductive materials 116 and 124, 130, or 124/130 may also comprise a part of the source and drain regions 142, for example. A channel region 122 of the transistor 140 is located beneath the gate dielectric 106 between the source region and the drain regions 142.

A silicide region 134 may be formed over the source and drain regions 142, e.g., over the second semiconductive material 124, 130, or 124/130, as shown in FIG. 6. The silicide region 134 may be formed by depositing a silicidation metal over the source and drain regions, e.g., over all exposed surfaces of the structure, and then subjecting the workpiece 102 to an annealing process. The hard mask 110 may be removed so that a silicide region 134 also forms over the gate 108, as shown. The silicidation metal may comprise nickel, cobalt, copper, molybdenum, titanium, tantalum, tungsten, erbium, zirconium, platinum, or combinations thereof, as examples. After the metal is deposited over at least the source and drain region 142 and optionally also over the gate 108, the workpiece 102 is heated, causing the metal to diffuse into at least the second semiconductive material 124, 130, or 124/130 and the gate 108, and optionally in some embodiments, also the first semiconductive material 116, if portions of the first semiconductive material 116 are adjacent to the metal. A silicide region 134 comprising a silicide of the metal is formed over the second semiconductive material 124, 130, or 124/130 and optionally also over portions of the first semiconductive material 116, for example. After the silicide region 134 is formed, the layer of silicidation metal is then removed from the semiconductor device 100. The silicide regions 134 improve the conductivity and reduce the resistance of the source and drain regions and optionally also the gate 108, for example. The silicide 134 may partially consume the underlying second semiconductive material 124, 130, or 124/130, as shown, or the silicide 134 may completely consume the second semiconductive material (e.g., if layer 130 comprises silicon), for example, not shown in the drawings.

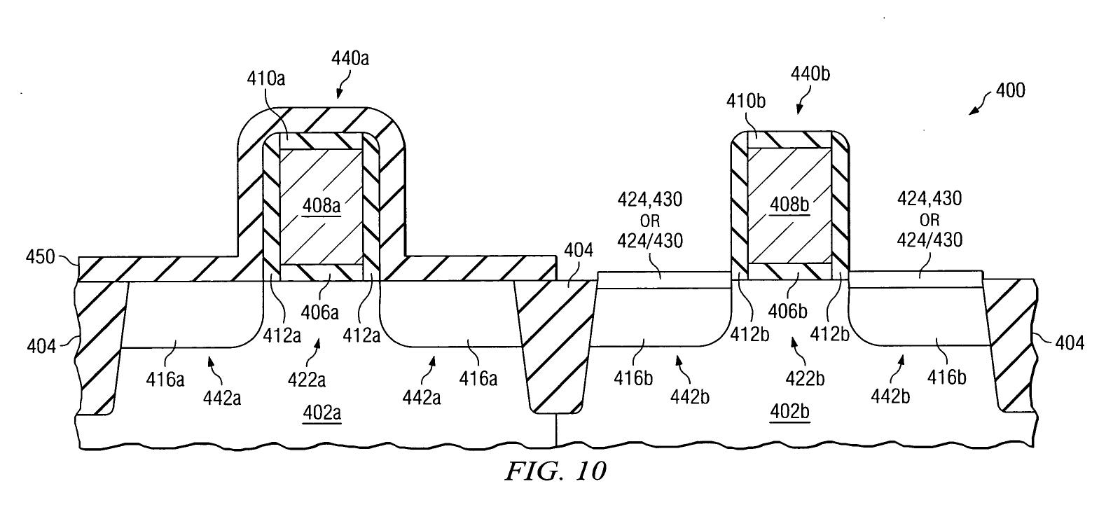

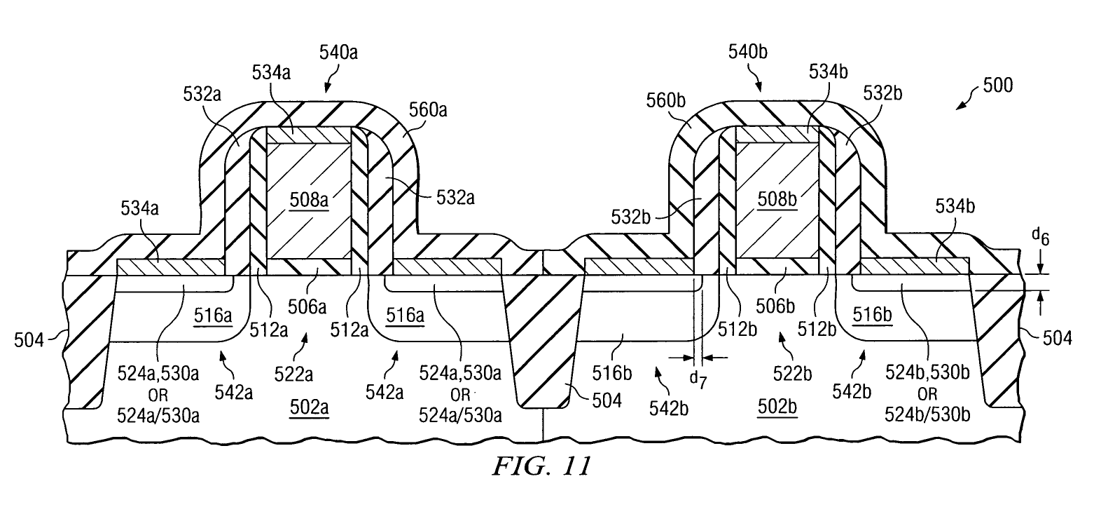

An optional stress-inducing nitride layer which may also function as a contact etch stop layer may be formed over the transistor 130 at this point (not shown in FIG. 6; see FIG. 10 at 450). An interlayer dielectric (ILD) layer 136 is then formed over the nitride layer. The ILD layer 136 preferably comprises an insulating material, and preferably comprises a material such as borophosphosilicate glass (BPSG), phosphosilicate glass (PSG), boron-doped silicon glass (BSG), organo-silicate glass (OSG), fluorinated silicate glass (FSG), spun-on-glass (SOG), silicon nitride, silicon dioxide, or plasma enhanced tetraethyloxysilane (PETEOS), as examples, although alternatively, the ILD layer 136 may comprise other materials.

The ILD layer 136 is etched to form contact holes using lithography, and source and drain contacts 138 are formed through the ILD layer 136 by depositing conductive material to fill the contact holes and make electrical contact to the silicided 134 source/drain regions 142. Note that the semiconductor device 100 also includes metallization layers (not shown) disposed above the ILD layer 136 and the source and drain contacts 138 that interconnect the various components of the semiconductor device 100. Other insulating materials and conductive materials may be formed over the transistor 140 and patterned to make electrical contact to portions of the transistor 140, for example, not shown. The semiconductor device 100 may be annealed to activate the dopants implanted during the various implantation steps, for example.

FIG. 7 shows a cross-sectional view of another preferred embodiment of the present invention, wherein a subsequent manufacturing process after the formation of second sidewall spacers 232 results in the inadvertent removal of a portion of the first material 216 from within the recesses. Like numerals are used the various elements that were used to describe the elements in FIGS. 1 through 6. To avoid repetition, each reference number shown in FIG. 7 is not described again in detail herein. Rather, similar materials x02, x04, x06, x08, etc . . . are preferably used for the various material layers shown as were described for FIGS. 1 through 6, where x=1 in FIGS. 1 through 6 and x=2 in FIG. 7. As an example, the preferred and alternative materials and dimensions described for the first material 116 in the description for FIGS. 1 through 6 are preferably also used for the first material 216 shown in FIG. 7.

In this embodiment, the first material 216 is unintentionally recessed by a manufacturing process of the semiconductor device 200 by an amount d₆ below a top surface of the workpiece 202. The first material 216 may also be unintentionally undercut beneath the second sidewall spacers 232 by the manufacturing process, e.g., by a dimension d₇. Dimensions d₆ and d₇ may comprise about 100 nm or less, for example, although alternatively, the amount of recess and undercut may comprise other dimensions. The unintentional recessing of the first material 216 during the manufacturing process of the transistor 240 occurs after the formation of the second sidewall spacers 232 in this embodiment.

The second sidewall spacers 232 may comprise an oxide liner and a nitride material disposed over the oxide liner, for example. The undercut may reside beneath the second sidewall spacers 232, e.g., undercutting the oxide liner of the second sidewall spacers 232.

FIG. 8 shows the embodiment of FIG. 7 after a second material 224, 230, or 224/230 is used to fill the area where the portion of the first material 216 was inadvertently removed. The second material 224, 230, or 224/230 may extend above a top surface of the workpiece 202 by an amount d₈, as shown, wherein d₈ comprises about 0 to 50 nm, as an example. FIG. 8 also shows the embodiment of FIG. 7 after the formation of a silicide 234 over the second material 224, 230, or 224/230 and optionally also over the gate 208. The silicide 234 may consume a top portion of the second material 224, 230, or 224/230 and the gate 208 material.

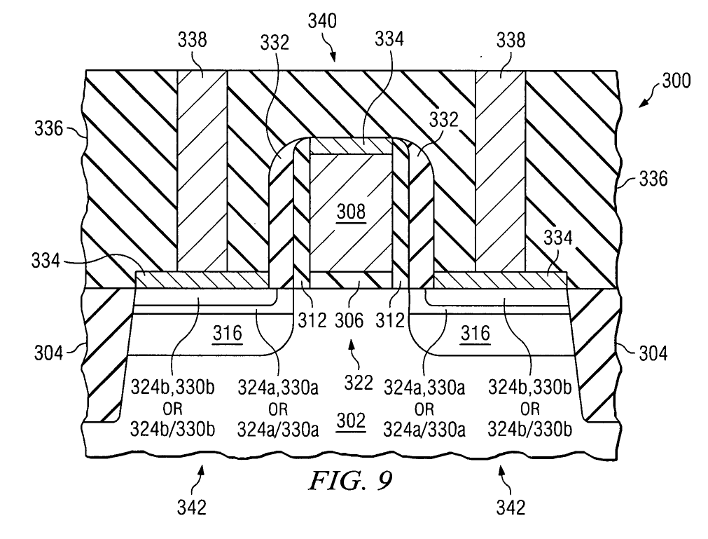

FIG. 9 shows a cross-sectional view of yet another preferred embodiment of the present invention, wherein manufacturing processes performed after both the first and second sidewall spacers 312 and 332 are formed cause unintended recessing of the source and drain 342 material, and the recesses are filled in two deposition or growth processes after the recessing occurs. Again, like numerals are used for the various elements that were used to describe the previous figures, and to avoid repetition, each reference number shown in FIG. 9 is not described again in detail herein.

FIG. 9 illustrates that the repair process to repair recessing of the source and drain 342 material in accordance with embodiments of the present invention may advantageously be repeated as many times as needed, to fill the source and drain 342 region material. For example, the source and drain region 342 are recessed after the formation of the first sidewall spacers 312, and the recesses are filled with the first material 316. A first manufacturing process is used to process the device 300, which results in the inadvertent removal of a top portion of the first material 316. A second material 324a, 330a, or 324a/330a is used to fill the top portion of the recess to replace the removed top portion of the first material 316, as shown. In the example shown, the second material 324a, 330a, or 324a/330a also overfills the recess, as shown in FIG. 9 proximate the channel 322 and the lower portion of the first sidewall spacer 312.

Next, the second sidewall spacers 332 are formed, and a second manufacturing process is used to process the device 300, e.g., to affect the workpiece 302 or a material layer disposed over the workpiece 302 (not shown), wherein the second manufacturing process results in the inadvertent removal of a top portion of the second material 324a, 330a, or 324a/330a. The removal of the second material 324a, 330a, or 324a/330a may also result in an undercutting of the second sidewall spacer 332, as shown. A third material 324b, 330b, or 324b/330b comprising similar materials and combinations thereof as described herein for the second material (e.g., second material 124, 130, or 124/130 of FIGS. 5a, 5b, and 5c), for example, is used to fill the recessed and removed second material 324a, 330a, or 324a/330a, as shown in FIG. 9, replacing the removed portion of the second material 324a, 330a, or 324a/330a and optionally also overfilling the recess above a top surface of the workpiece 302.

The repair and refill process using additional second material layers may be repeated as many times as needed, at various stages in the manufacturing process of a device 300. For example, in the embodiment shown in FIG. 9, after replacing the removed portion of the second material 324a, 330a, or 324a/330a with the third material 324b, 330b, or 324b/330b, at least one third manufacturing process may be used to affect the workpiece 302, wherein the at least one third manufacturing process inadvertently causes a top portion of the third material 324b, 330b, or 324b/330b to be removed. The removed top portion of the third material 324b, 330b, or 324b/330b is then replaced with at least one fourth material, wherein the fourth material comprises similar materials and combinations thereof as described herein for the second material (e.g., second material 124, 130, or 124/130 of FIGS. 5a, 5b, and 5c), for example.

Note that in some embodiments, overfilling the recessed first material 316, second material 324a, 330a, 324a/330a, or third material 324b, 330b, 324b/330b advantageously may avoid the need to form an additional fill material, because a subsequent manufacturing process that may recess the material in the source and drain regions 342 may result in the removal of the overfill material rather than forming an additional recess in the source and drain region 342 below a top surface of the workpiece 302, for example.

Embodiments of the present invention may be implemented in PMOS transistors. In these embodiments, the first semiconductive material 116, 216, and 316 preferably comprises SiGe or carbon-doped SiGe, which introduce or increase tensile stress of the source and drain regions 142, 242, and 342. Increasing the tensile stress of the source and drain regions 142, 242, and 342 creates compressive stress on the channel regions 122, 222, and 322 and improves device 100, 200, and 300 performance.

Embodiments of the present invention may also be implemented in NMOS transistors. In these embodiments, the first semiconductive material 116, 216, and 316 preferably comprises SiC, which introduces or increases compressive stress of the source and drain regions 142, 242, and 342. Increasing the compressive stress of the source and drain regions 142, 242, and 342 creates tensile stress on the channel regions 122, 222, and 322 and improves device 100, 200, and 300 performance.

Embodiments of the present invention may also be implemented in a CMOS device, on either the PMOS FET or the NMOS FET of the CMOS device. FIG. 10 shows a cross-sectional view of an embodiment of the present invention implemented in one FET of a CMOS device, as an example. Again, like numerals are used for the various elements that were used to describe the previous figures, and to avoid repetition, each reference number shown in FIG. 10 is not described again in detail herein.

One transistor, e.g., transistor 440a, may be masked with a masking material 450, which may also serve other purposes in the manufacturing process, such as introducing stress or serving as an etch stop layer, while the novel repair and first material 416b replacement processes described herein are performed on the other transistor 440b, forming the second material 424, 430, or 424/430 over regions where the top portion of the first material 416b was inadvertently and unintentionally removed during a manufacturing process for the semiconductor device 400.

FIG. 11 illustrates a cross-sectional view of embodiments of the present invention implemented in both an NMOS and a PMOS FET of a CMOS device. Again, like numerals are used for the various elements that were used to describe the previous figures, and to avoid repetition, each reference number shown in FIG. 11 is not described again in detail herein.

One transistor, e.g., transistor 540a, may be masked while the other transistor 540b is processed. Likewise, transistor 540b may be masked while the other transistor 540a is processed. In some embodiments, both transistors 540a and 540b may be processed simultaneously, for example. Masking and/or stress-inducing materials 560a and 560b may not be formed, and repair may be made to recesses formed in the first material 516a and 516b using the second material 524a, 530a, and 524a/530a and 524b, 530b, and 524b/530b, particularly if the second material comprises silicon, for example, which may advantageously be formed over both transistors 540a and 540b simultaneously, for example.

In some embodiments, for example, the CMOS device 500 preferably comprises a PMOS FET 540a that preferably comprises a first semiconductive material 516a comprising SiGe or carbon-doped SiGe, which increase tensile stress of the source and drain regions 542a and increase compressive stress on the channel region 522a, which is surrounded on either side by and adjacent to the source and drain regions 542a. The CMOS device 500 preferably comprises an NMOS FET 540b that preferably comprises a first semiconductive material 216b comprising SiC, which increases compressive stress of the source and drain regions 542b and increases tensile stress on the channel region 522b. The second semiconductive materials 524a, 530a, and 524a/530a and 524b, 530b, and 524b/530b may be silicided by silicide regions 534a and 534b, respectively.

Note that in some embodiments, if the second semiconductive materials 524a, 530a, and 524a/530a and 524b, 530b, and 524b/530b are silicided, preferably the silicide regions 534a and 534b do not extend above a top surface of the workpiece 502 along sidewalls of the sidewall spacers 532a and 532b.

Note also that in this embodiment, the device 500 may include stress liners 560a and 560b formed over a PMOS transistor 540a and an NMOS transistor 540b to further create stress on the transistors 540a and 540b, respectively. The stress liners 560a and 560b preferably create different types of stress on the transistors 540a and 540b, for example. Liner 560a preferably contains compressive stress and liner 560b preferably contains tensile stress, for example. The various types of stress may be created in a nitride material such as silicon nitride by changing the deposition temperature and various processing conditions, for example.

In some embodiments, to manufacture a CMOS device 500 such as the one shown in FIG. 11, an NMOS transistor 540b region may be covered with a masking material (not shown) while a PMOS transistor 540a region is processed in accordance with embodiments of the present invention. Likewise, the PMOS transistor 540a region may be covered with a masking material while the NMOS transistor 540b region is processed (not shown). The masking material may comprise a disposable spacer comprising a nitride material, for example, although other materials may also be used.

Embodiments of the present invention may be implemented in applications where transistors are used, as described herein and shown in the figures. One example of a memory device that embodiments of the present invention may be implemented in that uses both PMOS FET's and NMOS FET's is a static random access memory (SRAM) device. A typical SRAM device includes arrays of thousands of SRAM cells, for example. Each SRAM cell may have four or six transistors (for example). A commonly used SRAM cell is a six-transistor (6T) SRAM cell, which has two PMOS FET's interconnected with four NMOS FET's. The novel methods and structures that introduce strain to the channel regions of transistors described herein may be implemented in the transistors of SRAM devices and other memory devices, for example.

Embodiments of the present invention may be implemented in transistors wherein the source and drain regions are formed using an “early eSiGe” process or a “later eSiGe” process. For example, in an “early eSiGe” process, the source and drain regions 142/242/342/442/542 are recessed and filled with a first material 116/216/316/416a/416b/516a/516b after the formation of first sidewall spacers 112/212/312/412a/412b/512a/512b. The first sidewall spacers 112/212/312/412a/412b/512a/512b may comprise disposable spacers that are replaced later with permanent first sidewall spacers 112/212/312/412a/412b/512a/512b, or the first sidewall spacers 112/212/312/412a/412b/512a/512b may comprise permanent spacers that are left remaining in the structure, for example. In a “late eSiGe” process, the source and drain regions are recessed and filled with a first material 116/216/316/416a/416b/516a/516b after the formation of second sidewall spacers 132/232/332/432a/432b/532a/532b. Some transistor 140/240/340/440a/440b/540a/540b designs may require a wider channel region 122/222/322/422a/422b/522a/522b or larger light or deep implantation regions proximate the source and drain regions 142/242/342/442/542, for example. Embodiments of the present invention may be used to repair or replace inadvertently removed first material 116/216/316/416a/416b/516a/516b in both “early eSiGe”-formed and “late eSiGe”-formed source and drain regions 142/242/342/442/542, for example.

Embodiments of the present invention may also be implemented in semiconductor device structures other than the transistors 140/240/340/440a/440b/540a/540b shown in the drawings. For example, in the embodiment shown in FIGS. 1 through 6, recesses 114 may be formed in a workpiece 102 and the first and second semiconductive materials 116 and 124, 130, and 124/130 may be used to fill the recesses 114 as described herein. The first material 116 may be adapted to alter the stress of an adjacent region within the workpiece 102 in other semiconductor device applications, for example, and the second material 116 and 124, 130, and 124/130 may be used to fill or repair damage or recesses that are inadvertently formed in the top surface of the first material 116 during other manufacturing processes of the semiconductor device 100.

Embodiments of the present invention include semiconductor devices and transistors that include the first materials 116, 216, 316, 416, and 516 and second materials 124, 130, or 124/130; 224, 340, or 224/230; 324a, 330a, or 324a/330a; 324b, 330b, or 324b/330b; 424, 430, or 424/430; 524a, 530a, or 524a/530a; or 524b, 530b, or 524b/530b filling recesses inadvertently formed in the first materials 116, 216, 316, 416, and 516 or previously formed second materials 124, 130, or 124/130; 224, 340, or 224/230; 324a, 330a, or 324a/330a; 324b, 330b, or 324b/330b; 424, 430, or 424/430; 524a, 530a, or 524a/530a; or 524b, 530b, or 524b/530b described herein. Embodiments of the present invention also include methods of fabricating the semiconductor devices 100, 200, 300, 400, and 500 and transistors 140, 240, 340, 440a, 440b, 540a, and 540b described herein, for example.

Advantages of embodiments of the invention include providing novel structures and methods for repairing material layers that are unintentionally damaged or partially removed during manufacturing processes. The material layers, e.g., the first material 116, 216, 316, 416, and 516, may be adapted to alter the stress of channel regions of transistors, by altering the stress of source and drain regions of transistors using the first materials and optionally also the second materials 124, 130, or 124/130; 224, 340, or 224/230; 324a, 330a, or 324a/330a; 324b, 330b, or 324b/330b; 424, 430, or 424/430; 524a, 530a, or 524a/530a; or 524b, 530b, or 524b/530b in some embodiments. In some embodiments, the second material 124, 130, or 124/130; 224, 340, or 224/230; 324a, 330a, or 324a/330a; 324b, 330b, or 324b/330b; 424, 430, or 424/430; 524a, 530a, or 524a/530a; or 524b, 530b, or 524b/530b improves the formation of the silicide regions, ensuring a better contact of the silicide material with the second material 124, 130, or 124/130; 224, 340, or 224/230; 324a, 330a, or 324a/330a; 324b, 330b, or 324b/330b; 424, 430, or 424/430; 524a, 530a, or 524a/530a; or 524b, 530b, or 524b/530b, reducing sheet resistance and improving conductivity, which also improves the transistor 140, 240, 340, 440a, 440b, 540a, and 540b and device performance.

Embodiments of the present invention are easily implementable in existing manufacturing process flows, with a small or reduced number of additional processing steps being required, particularly if the first material 116, 216, 316, 416, and 516 and second material 124, 130, or 124/130; 224, 340, or 224/230; 324a, 330a, or 324a/330a; 324b, 330b, or 324b/330b; 424, 430, or 424/430; 524a, 530a, or 524a/530a; or 524b, 530b, or 524b/530b are formed using in-situ epitaxial growth processes, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, the method comprising:
providing a semiconductor wafer;
forming a first material on the semiconductor wafer;
affecting the semiconductor wafer with a manufacturing process, wherein the manufacturing process inadvertently causes a portion of the first material to be removed; and
replacing the portion of the first material with a second material.

2. The method according to claim 1, wherein replacing the portion of the first material with the second material comprises forming the same material as the first material, a different material than the first material, or combinations or multiple layers thereof.

3. The method according to claim 1, wherein affecting the semiconductor wafer with the manufacturing process comprises using a manufacturing process comprising a cleaning process, a polishing process, an etch process or removal process for a material layer of the semiconductor device other than the first material, or combinations thereof.

4. The method according to claim 1, wherein affecting the semiconductor wafer with the manufacturing process comprises affecting the semiconductor wafer with a first manufacturing process, further comprising, after replacing the portion of the first material with the second material:
affecting the semiconductor wafer with a second manufacturing process, wherein the second manufacturing process inadvertently causes a portion of the second material to be removed; and
replacing the portion of the second material with a third material.

5. The method according to claim 4, further comprising, after replacing the portion of the second material with the third material:
affecting the semiconductor wafer with at least one third manufacturing process, wherein the at least one third manufacturing process inadvertently causes a portion of the third material to be removed; and
replacing the portion of the third material with at least one fourth material.

6. The method according to claim 1, wherein forming the first material comprises forming a compound semiconductor material, and wherein forming the second material comprises forming a compound semiconductor material, forming a single element semiconductor material, or forming a first layer of a compound semiconductor material and forming second layer of a single element semiconductor material over the first layer of the compound semiconductor material.

7. A method of manufacturing a semiconductor device, the method comprising:
providing a workpiece;
forming at least one recess in the workpiece;
filling the at least one recess with a first semiconductive material;
affecting the workpiece with a manufacturing process, wherein the manufacturing process inadvertently causes a portion of the first semiconductive material to be removed from within the at least one recess; and
replacing the removed portion of the first semiconductive material with a second semiconductive material.

8. The method according to claim 7, further comprising forming a silicide over at least the second semiconductive material.

9. The method according to claim 8, wherein replacing the removed portion of the first semiconductive material with the second semiconductive material comprises forming a second semiconductive material comprising a material that improves the forming of the silicide.

10. The method according to claim 7, wherein filling the at least one recess with the first semiconductive material and replacing the removed portion of the first semiconductive material with the second semiconductive material comprise forming a source region or a drain region of a transistor.

11. The method according to claim 7, wherein forming the first semiconductive material comprises forming a material that alters a stress of the workpiece proximate the first semiconductive material.

12. The method according to claim 7, wherein replacing the removed portion of the first semiconductive material with the second semiconductive material comprises using a deposition process or an epitaxial growth process to form the second semiconductive material.

13. The method according to claim 7, wherein filling the at least one recess with the first semiconductive material comprises forming the first semiconductive material above a top surface of the workpiece by about 0 to 50 nm, or wherein replacing the removed portion of the first semiconductive material with the second semiconductive material comprises forming the second semiconductive material above the top surface of the workpiece by about 0 to 50 nm.

14. A method of manufacturing a transistor, the method comprising:
providing a workpiece;
forming a gate dielectric material over the workpiece;
forming a gate material over the gate dielectric material;
patterning the gate material and the gate dielectric material to form a gate and a gate dielectric, the gate and the gate dielectric comprising sidewalls;
forming at least one sidewall spacer over the sidewalls of the gate and the gate dielectric;
forming recesses in the workpiece proximate the at least one sidewall spacer;
filling the recesses in the workpiece with a first semiconductive material;
affecting the workpiece with at least one manufacturing process, wherein the at least one manufacturing process unintentionally results in a removal of a top portion of the first semiconductive material from within the recesses; and
forming a second semiconductive material over the first semiconductive material, replacing the removed top portion of the first semiconductive material.

15. The method according to claim 14, wherein forming the first semiconductive material comprises forming SiGe, carbon-doped SiGe, or SiC.

16. The method according to claim 14, wherein forming the second semiconductive material comprises forming Si, SiGe, carbon-doped SiGe, SiC, or combinations or multiple layers thereof.

17. The method according to claim 14, wherein forming the second semiconductive material comprises forming a first layer of SiGe, carbon-doped SiGe, or SiC, and forming a second layer of Si.

18. The method according to claim 14, wherein forming the at least one sidewall spacer comprises forming first sidewall spacers over the sidewalls of the gate and the gate dielectric and forming second sidewall spacers over the first sidewall spacers, before affecting the workpiece with the at least one manufacturing process and forming the second semiconductive material over the first semiconductive material.

19. The method according to claim 14, wherein forming the at least one sidewall spacer comprises:
forming first sidewall spacers over the sidewalls of the gate and gate dielectric, before affecting the workpiece with the at least one manufacturing process and forming the second semiconductive material over the first semiconductive material; and
forming second sidewall spacers over the first sidewall spacers, after forming the second semiconductive material over the first semiconductive material.

20. The method according to claim 14, wherein forming the at least one sidewall spacer comprises:
forming temporary sidewall spacers over the sidewalls of the gate and gate dielectric, before affecting the workpiece with the at least one manufacturing process and forming the second semiconductive material over the first semiconductive material;
removing the temporary sidewall spacers;
forming first sidewall spacers over the sidewalls of the gate and gate dielectric; and
forming second sidewall spacers over the first sidewall spacers.

21. The method according to claim 14, wherein affecting the workpiece with the at least one manufacturing process comprises undercutting a portion of the first semiconductive material from beneath the at least one sidewall.

22. A transistor, comprising:
a workpiece;
a channel region disposed within the workpiece, the channel region comprising a first side and a second side opposite the first side;
a gate dielectric disposed over the channel region;
a gate disposed over the gate dielectric, the gate and the gate dielectric having sidewalls;
at least one sidewall spacer disposed over the sidewalls of the gate and the gate dielectric;
a source region disposed within the workpiece proximate the first side of the channel region; and
a drain region disposed within the workpiece proximate the second side of the channel region, the source region and the drain region comprising a first semiconductive material in a lower portion and a second semiconductive material in an upper portion, wherein a portion of the second semiconductive material is disposed beneath the at least one sidewall spacer.

23. The transistor according to claim 22, wherein the at least one sidewall spacer comprises a first sidewall spacer and a second sidewall spacer disposed over the first sidewall spacer, and wherein the portion of the second semiconductive material disposed beneath the at least one sidewall spacer is disposed beneath a portion of the first sidewall spacer, the second sidewall spacer, or both the first sidewall spacer and the second sidewall spacer.

24. The transistor according to claim 22, wherein the transistor comprises a p channel metal oxide semiconductor (PMOS) field effect transistor (FET), and wherein the first semiconductive material increases a tensile stress of the source region and the drain region.

25. The transistor according to claim 22, wherein the transistor comprises an n channel metal oxide semiconductor (NMOS) field effect transistor (FET), and wherein the first semiconductive material increases a compressive stress of the source region and the drain region.

26. A complementary metal oxide semiconductor (CMOS) device including the transistor of claim 22.
